(19) United States
(12) Patent Application Publication
(10) Pub. No.: US 2010/0293418 A1
(43) Pub. Date: Nov. 18, 2010

(54) MEMORY DEVICE, DATA TRANSFER CONTROL DEVICE, DATA TRANSFER METHOD, AND COMPUTER PROGRAM PRODUCT

(75) Inventor: Yasuyuki NAGASHIMA, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: TOSHIBA STORAGE DEVICE CORPORATION, Tokyo (JP)

(21) Appl. No.: 12/781,634

(22) Filed: May 17, 2010

(30) Foreign Application Priority Data
May 15, 2009 (JP) 2009-119302

(51) Int. Cl. G06F 11/16; G11C 29/00; G06F 12/02; G06F 11/00

(52) U.S. Cl. 714/54; 714/764; 711/171; 711/E12.001; 711/173; 711/E12.002; 714/E11.056

(57) ABSTRACT

According to one embodiment, a memory device includes: a driving module configured to store therein data on a sector-by-sector basis; a first verifying module configured to verify, during a reading operation, sector data from the driving module; a partitioning module configured to partition the sector data into sets of subsector data, a size of each set of subsector data being smaller than a size of the sector data; an appending module configured to append an error detecting code to each set of subsector data; a second verifying module configured to store, in a predetermined memory, the sets of subsector data retrieved from a buffer, and to verify the sets of subsector data using respective error detecting codes; and a sending module configured to send, from the memory, the verified sets of subsector data to the host with a transfer size.

### CROSS-REFERENCE TO RELATED APPLICATIONS

This application is based upon and claims the benefit of priority from Japanese Patent Application No. 2009-119302, filed on May 15, 2009, the entire contents of which are incorporated herein by reference.

### BACKGROUND

1. Field

One embodiment of the invention relates to a memory device, a data transfer control device, a data transfer method, and a computer program product.

2. Description of the Related Art

Typically, in a large-scale computer system, a storage device equipped with a plurality of disks is used. A storage device performs reading or writing of data generally on a sector-by-sector basis. More particularly, while performing a writing operation, a storage device partitions the data received from a host apparatus into sets of data equivalent to the sector size, appends an error detecting code to each set of the partitioned data, and writes that data in a disk. On the other hand, while performing a reading operation, a storage device reads sets of data on a sector-by-sector basis from a disk, verifies the read data using respective error detecting codes, and sends the verified data to a host apparatus.

Given below is the description with reference to FIG. 10 about data communication performed by a conventional storage device. FIG. 10 is a schematic diagram of exemplary data communication performed by a conventional storage device. In the example illustrated in FIG. 10, a conventional storage device 900 comprises a driving module 901 and a memory 902. The driving module 901 is, for example, a memory such as a magnetic disk that is used to store a variety of data. The memory 902 is, for example, a memory for data management using the first in first out (FIFO) technique.

In the example illustrated in FIG. 10, it is assumed that the transfer size of data to be communicated between a host apparatus 1 and the storage device 900 is 1024 bytes and the size of a single sector is 512 bytes.

While performing a writing operation under the abovementioned conditions, the storage device stores the data received from the host apparatus 1 in the memory 902. Since the transfer size of data is 1024 bytes, the storage device 900 stores 1024 bytes of data in the memory 902. Then, the storage device 900 partitions the data stored in the memory 902 into sets of data equivalent to the sector size, appends an error detecting code to each set of the partitioned sector data, and stores that data in a predetermined buffer. Subsequently, the storage device 900 performs a verification operation with respect to the sector data stored in the buffer and stores the verified data in the driving module 901. Herein, since the sector size is 512 bytes, the storage device 900 partitions the data, which is stored in the memory 902, into two sets of sector data and stores it in the driving module 901.

On the other hand, while performing a reading operation, the storage device reads data on a sector-by-sector basis from the driving module 901, stores the read sector data first in a predetermined buffer and then in the memory 902, and performs a verification operation with respect to the stored data. When the size of the data stored in the memory 902 reaches the transfer size, the storage device 900 sends that data from the memory 902 to a host apparatus. Herein, since the sector size is 512 bytes and the transfer size of data is 1024 bytes, the storage device 900 transfers data to a host apparatus when two verified sets of data get stored in the memory 902.

In this way, by sending the verified data to the host apparatus 1, the storage device 900 ensures that no data including an error is sent to the host apparatus 1 (for example, Japanese Patent Application (KOKAI) No. 2005-354652).

Meanwhile, in recent years, the trend is to expand the sector size in order to enhance the data correction capability or to increase the recording capacity. However, in the above-mentioned conventional technology, expanding the sector size leads to the use of a large memory capacity.

The explanation regarding that issue is given below with reference to the example illustrated in FIG. 10. Herein, in an identical manner to the abovementioned example, it is assumed that the sector size is 512 bytes and the transfer size of data is 1024 bytes. As described above, while performing a reading operation, the conventional storage device 900 stores the sector data in the memory 902 and performs a verification operation with respect to the stored data. When the size of the data stored in the memory 902 reaches the transfer size, the storage device 900 transfers the stored data. That is, in the abovementioned example, it is necessary that the memory 902 has the capacity of at least 1024 bytes.

Moreover, if the sector size is 512 bytes and the transfer size is 1024 bytes; then, although depending on the system, the memory 902 is generally designed to have a capacity of 1536 bytes, which is the triple of 512 bytes, in order to allow some margin in the memory 902.

If, for example, the sector size is expanded to 4 kilobytes (KB) (i.e., 4096 bytes); then, while performing a reading operation, the conventional storage device 900 stores the sector data equivalent to 4 KB in the memory 902 and performs a verification operation with respect to the stored data. Thus, the memory 902 is required to have a capacity of at least 4 KB or more. Since the memory 902 is generally allowed some margin as described above, it is presumable that the memory 902 would be designed to have a capacity of 8 KB, which is the double of 4 KB.

In this way, in the case of using a conventional storage device, expansion in the sector size leads to a need to increase the memory capacity. What that means is that more memory needs to be added, which drives up the price of the storage device.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary schematic diagram of a memory device according to a first embodiment of the invention;

FIG. 2 is an exemplary schematic diagram of a storage device according to a second embodiment of the invention;

FIG. 3 is an exemplary schematic diagram of processing performed during a reading operation by a first verifying module and a buffer manager in the second embodiment;

FIG. 4 is an exemplary schematic diagram of processing performed during a reading operation by a second verifying module and an interface control module in the second embodiment;

FIG. 5 is an exemplary schematic diagram processing performed during a writing operation by the second verifying module and the buffer manager in the second embodiment;

FIG. 6 is an exemplary schematic diagram of an example of processing performed during a writing operation by the first verifying module and a drive control module in the second embodiment;

FIG. 7 is an exemplary flowchart of a reading operation performed by the storage device in the second embodiment;

FIG. 8 is an exemplary flowchart of a writing operation performed by the storage device in the second embodiment;

FIG. 9 is an exemplary schematic diagram of a computer that executes a data transfer program according to an embodiment of the invention; and

FIG. 10 is an exemplary schematic diagram of data communication performed by a conventional storage device.

### DETAILED DESCRIPTION

Various embodiments of a memory device, a data transfer control device, a data transfer method, and a computer program product according to the invention will be described hereinafter with reference to the accompanying drawings. The present invention is not limited to the memory device, the data transfer control device, the data transfer method, and the computer program product explained in the following embodiments. In general, according to one embodiment of the invention, a memory device configured to communicate data of a predetermined transfer size with respect to a host, the memory device comprises: a driving module configured to store data on a sector-by-sector basis; a first verifying module configured to verify, during a reading operation, sector data read on the sector-by-sector basis from the driving module; a partitioning module configured to partition the sector data verified by the first verifying module into sets of subsector data, a size of each set of subsector data being smaller than a size of the sector data; an appending module configured to append an error detecting code to each set of subsector data; a second verifying module configured to store, in a predetermined memory, the sets of subsector data from a buffer for storing the sets of subsector data appended with respective error detecting codes by the appending module, and configured to verify the sets of subsector data in the memory using respective error detecting codes appended by the appending module; and a transmitter configured to read, from the memory, the sets of subsector data verified by the second verifying module, and configured to transmit the verified sets of subsector data to the host with the transfer size.

According to another embodiment of the invention, a data transfer control device for controlling a memory device configured to communicate data of a predetermined transfer size with respect to a host, the data transfer control device comprises: a first verifying module configured to verify, during a reading operation, sector data read on a sector-by-sector basis from a driving module that is used in storing data on the sector-by-sector basis; a partitioning module configured to partition the sector data verified by the first verifying module into sets of subsector data, a size of each set of subsector data being smaller than a size of the sector data; an appending module configured to append an error detecting code to each set of partitioned subsector data; a second verifying module configured to store, in a predetermined memory, the sets of subsector data from a buffer for storing the sets of subsector data appended with respective error detecting codes by the appending module, and configured to verify the sets of subsector data in the memory using respective error detecting codes appended by the appending module; and a transmitter configured to read, from the memory, the sets of subsector data verified by the second verifying module, and configured to transmit the verified sets of subsector data to the host by the transfer size.

According to still another embodiment of the invention, a data transfer method performed by a memory device configured to communicate data of a predetermined transfer size with respect to a host, the data transfer method comprises: first verifying, during a reading operation, sector data read on a sector-by-sector basis from a driving module that is used in storing data on the sector-by-sector basis; partitioning the verified sector data into sets of subsector data, a size of each set of subsector data being smaller than a size of the sector data; appending an error detecting code to each set of partitioned subsector data; storing, in a predetermined memory, the sets of subsector data from a buffer for storing the sets of subsector data appended with respective error detecting codes, verifying the sets of subsector data stored in the memory using respective appended error detecting codes; and reading, from the memory, the verified sets of subsector data, and sending the verified sets of subsector data to the host with the transfer size.

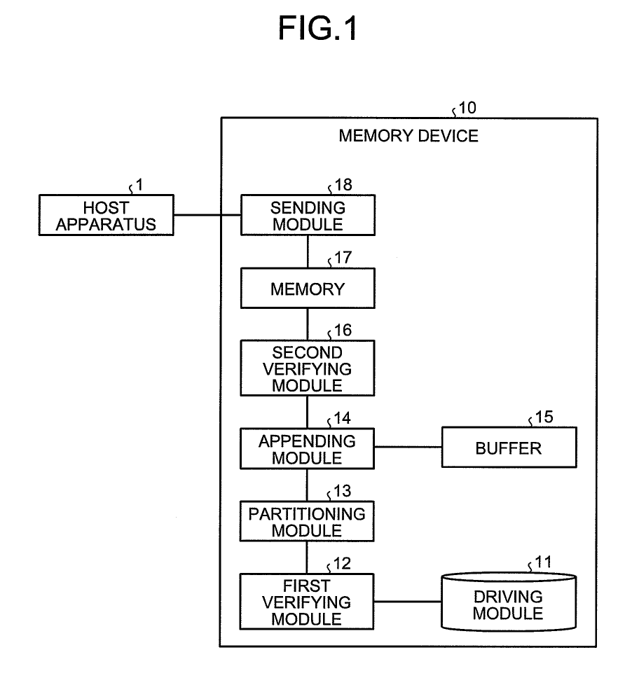

Given below is the description with reference to FIG. 1 about a configuration of the memory device according to a first embodiment. FIG. 1 is a schematic diagram of an exemplary configuration of the memory device according to the first embodiment. In the example illustrated in FIG. 1, a memory device 10 according to the first embodiment is connected to the host apparatus 1, and sends and receives data with respect to the host apparatus 1 by a predetermined transfer size. As illustrated in the example in FIG. 1, the memory device 10 comprises a driving module 11, a first verifying module 12, a partitioning module 13, an appending module 14, a buffer 15, a second verifying module 16, a memory 17, and a sending module 18.

Given below is the explanation of the processing performed by each constituent element during a reading operation. The driving module 11 stores therein, on a sector-by-sector basis, data appended with an error detecting code. During a reading operation, the first verifying module 12 reads data on a sector-by-sector basis from the driving module 11 and verifies the read data using the respective error detecting codes.

The partitioning module 13 partitions each set of the sector data that has been verified by the first verifying module 12 into sets of data of a smaller size than the corresponding sector size. Hereinafter, each smaller sector of a partitioned sector is referred to as “subsector” and each set of data of each of the partitioned sector data is referred to as “subsector data”.

The appending module 14 appends an error detecting code to each set of the subsector data that has been obtained with partitioning performed by the partitioning module 13. The buffer 15 stores therein the sets of subsector data, each being appended with an error detecting code by the appending module 14.

The second verifying module 16 reads the sets of subsector data from the buffer 15, stores the read subsector data in the memory 17, and verifies the subsector data using the respective error detecting codes appended by the appending module 14. The memory 17 is a memory device used to temporarily store a variety of data. The sending module 18 reads, from the memory 17, the sets of subsector data that have been verified by the second verifying module 16 and sends at one time the subsector data equivalent to the transfer size to the host apparatus 1.

As described above, while performing a reading operation, the memory device 10 according to the first embodiment partitions the sector data read from the driving module 11 into sets of subsector data, appends an error detecting code to each set of the subsector data, and then stores the sets of subsector data in the buffer 15. Then, the memory device 10 reads each set of the subsector data from the buffer 15, stores that sets of subsector data in the memory 17, and performs a verification operation with respect to the stored set of subsector data. Subsequently, every time the size of the verified sets of subsector data reaches the transfer size, the memory device 10 sends that data from the memory 17 to the host apparatus 1.

In this way, even if the sector size of the driving module 11 is large, the memory device 10 according to the first embodiment stores the sets of subsector data obtained with partitioning in the memory 17. Hence, the memory 17 is saved from being used in a large capacity.

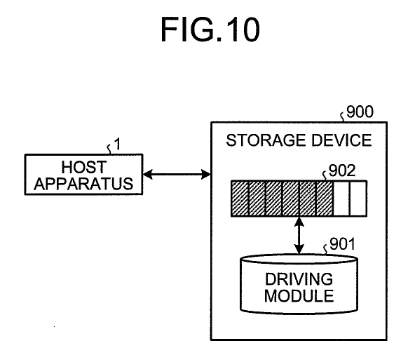

For example, consider the comparison with the storage device 900 illustrated in FIG. 10. As described above, if the sector size is 4 KB; then, while performing a reading operation, the storage device 900 illustrated in FIG. 10 stores the sector data equivalent to 4 KB in the memory 902 and performs a verification operation with respect to the stored sector data. Thus, the memory 902 is required to have a capacity of at least 4 KB.

In contrast, irrespective of whether the sector size is 4 KB, the memory device 10 illustrated in FIG. 1 stores the sets of subsector data obtained with partitioning in the memory 17 and performs a verification operation with respect to the sets of subsector data. For example, in the case of partitioning the sector data into sets of subsector data equivalent to 512 bytes, the memory device 10 stores the sets of subsector data equivalent to 512 bytes in the memory 17 and performs a verification operation with respect to each set of the subsector data. In that case, it is sufficient if the memory 17 illustrated in FIG. 1 has a capacity equal to or larger than the transfer size of 1024 bytes. That is, when the memory device 10 partitions the sector data into sets of subsector data equivalent to 512 bytes, the memory 17 is required to have a capacity identical to the case when the sector size is 512 bytes. In this way, even if the sector size is large, the memory device 10 according to the first embodiment is able to perform data communication with only a small memory capacity.

As described above, the memory device 10 according to the first embodiment enables achieving expansion of the sector size without having to increase the capacity of the memory 17. For that reason, even if the sector size is large, the use of the memory device 10 according to the first embodiment ensures that additional memory is not required. Consequently, it becomes possible to prevent the price of the storage device from rising.

The following explanation is given for a specific example of the memory device 10 described above in the first embodiment. In a second embodiment, the description is given for an exemplary case when the memory device 10 according to the first embodiment functions as a storage device.

In the second embodiment, a cyclic redundancy check (CRC) is used as the error detecting code appended to data and an error correcting code (ECC) is used as the error correcting code appended to data. Moreover, in the second embodiment, a CRC code appended inside the storage device is referred to as “BCRC” and an ECC code appended inside the storage device is referred to as “BECC”. Furthermore, in the second embodiment, it is assumed that the size of a single sector is 4 KB, the size of a single subsector is 512 bytes, and the transfer size of data to be communicated with a host apparatus is 1024 bytes.

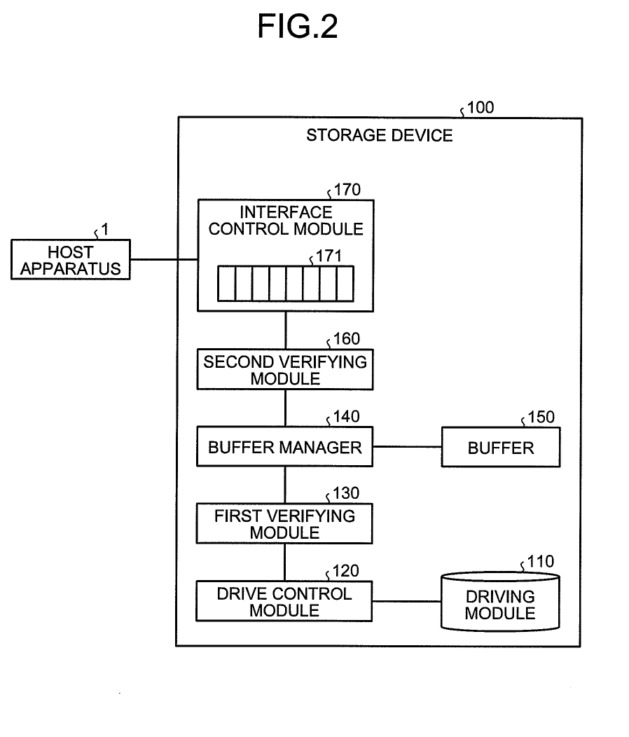

Given below is the description with reference to FIG. 2 about a configuration of the storage device according to the second embodiment. FIG. 2 is a schematic diagram of an exemplary configuration of the storage device according to the second embodiment. In the example illustrated in FIG. 2, a storage device 100 according to the second embodiment is connected to the host apparatus 1, and sends and receives data to the host apparatus 1 by a predetermined transfer size. As illustrated in the example in FIG. 2, the storage device 100 comprises a driving module 110, a drive control module 120, a first verifying module 130, a buffer manager 140, a buffer 150, a second verifying module 160, and an interface control module 170.

Regarding each constituent element of the storage device 100, the following explanation is given for a case (1) when the storage device 100 performs a reading operation and a case (2) when the storage device 100 performs a writing operation.

Explained below is the processing performed by each constituent element when the storage device 100 performs a reading operation. The driving module 110 is, for example, a memory such as a magnetic disk that is used to store a variety of data on a sector-by-sector basis. In the second embodiment, since the size of a single sector is 4 KB, the driving module 110 stores therein data equivalent to 4 KB on a sector-by-sector basis.

In the case when the storage device 100 performs a reading operation, the drive control module 120 reads data on a sector-by-sector basis from the driving module 110 and outputs each set of the read sector data to the first verifying module 130.

In the case when the storage device 100 performs a reading operation, the first verifying module 130 verifies, with the use of a BCRC appended to each set of the sector data received from the drive control module 120, whether that sector data includes an error. If an error is detected, then the first verifying module 130 corrects the error with the use of a BECC appended to the corresponding sector data.

Then, the first verifying module 130 removes the BCRC and the BECC from each set of the verified sector data and partitions each set of the sector data into sets of subsector data of a smaller size than the corresponding sector size. Subsequently, the first verifying module 130 calculates a BCRC and a BECC for each set of the subsector data obtained with partitioning and appends the calculated BCRC and BECC to the corresponding subsector data. In the second embodiment, it is assumed that the sector size is 4 KB and the subsector size is 512 bytes. Thus, the first verifying module 130 partitions each set of the sector data equivalent to 4 KB into sets of subsector data equivalent to 512 bytes. Meanwhile, the first verifying module 130 corresponds to the first verifying module 12, the partitioning module 13, and the appending module 14 illustrated in FIG. 1.

The buffer manager 140 controls the buffer 150. More particularly, in the case when the storage device 100 performs a reading operation, the buffer manager 140 stores in the buffer 150 the sets of subsector data appended with respective BCRC and BECC by the first verifying module 130. The buffer 150 is a cache for temporarily storing the data that is to be communicated between the host apparatus 1 and the storage device 100.

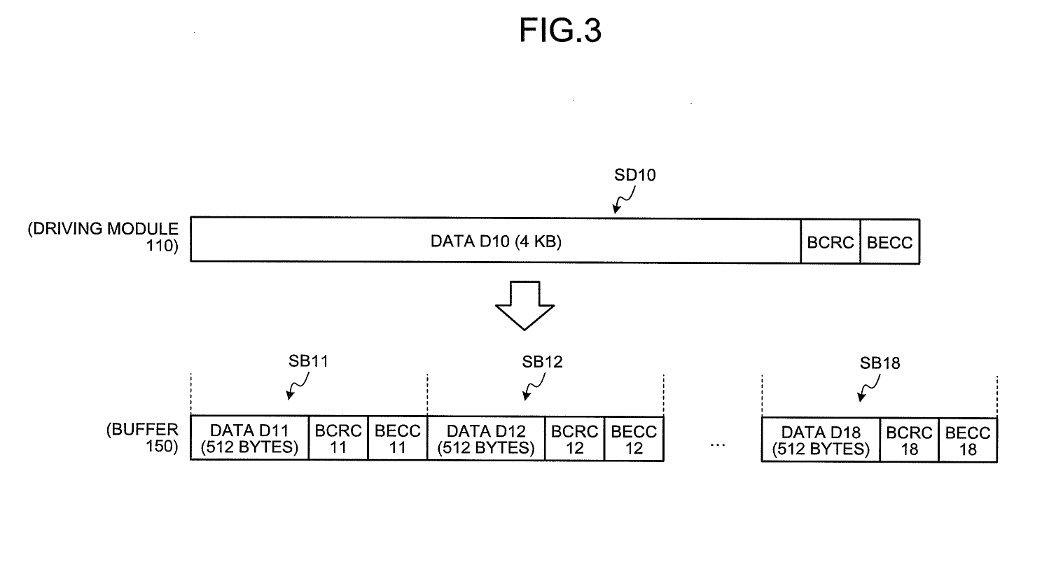

The processing performed by the first verifying module 130 and the buffer manager 140 is explained below with reference to FIG. 3. FIG. 3 is a schematic diagram of an example of the processing performed by the first verifying module 130 and the buffer manager 140 during a reading operation.

In the example illustrated in FIG. 3, the driving module 110 stores therein sector data SD10 equivalent to 4 KB. As illustrated in FIG. 3, the sector data SD10 includes data D10 appended with a BCRC and a BECC. Upon receiving input of the sector data SD10 illustrated in FIG. 3 from the drive control module 120, the first verifying module 130 verifies, with the use of the BCRC appended to the sector data SD10, whether the sector data SD10 includes an error. If an error is detected, then the first verifying module 130 corrects the error with the use of the BECC appended to the sector data SD10.

Then, as illustrated in the lower part of FIG. 3, the first verifying module 130 partitions the verified data D10 into eight sets of data D11 to D18, each equivalent to the size of 512 bytes. To the data D11 to D18, the first verifying module 130 appends respective BCRC and BECC. In the example illustrated in FIG. 3, the first verifying module 130 appends BCRC 11 and BECC 11 to the data D11 and appends BCRC 12 and BECC 12 to the data D12. In an identical manner, regarding the data D13 to D18, the first verifying module 130 respectively appends BCRC 13 to BCRC 18 and BECC 13 to BECC 18.

As illustrated in the lower part of FIG. 3, the buffer manager 140 then stores, in the buffer 150, subsector data SB11 to SB18 including respective BCRC and BECC appended by the first verifying module 130.

Returning to the explanation with reference to FIG. 2, in the case when the storage device 100 performs a reading operation, the second verifying module 160 reads the sets of subsector data from the buffer 150 via the buffer manager 140 and stores the read sets of subsector data in a memory 171 described later. Then, the second verifying module 160 verifies, with the use of the BCRC appended to each set of the subsector data, whether any set of the subsector data includes an error. If an error is detected, then the second verifying module 160 corrects the error with the use of the BECC appended to the corresponding subsector data.

The interface control module 170 controls an interface that is used in the data communication with the host apparatus 1. More particularly, the interface control module 170 performs data communication with the host apparatus 1 while storing the data in the memory 171 on a temporary basis. The memory 171 is, for example, a memory for data management using the FIFO technique. Meanwhile, the interface control module 170 corresponds to the memory 17 and the sending module 18 illustrated in FIG. 1.

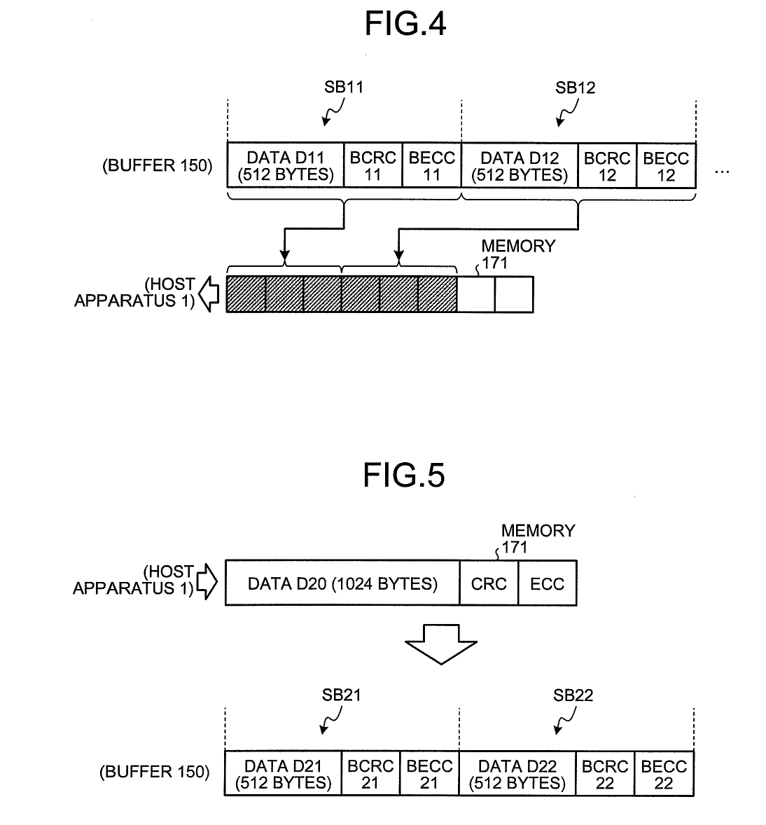

The processing performed by the second verifying module 160 and the interface control module 170 is explained below with reference to FIG. 4. FIG. 4 is a schematic diagram of an example of the processing performed by the second verifying module 160 and the interface control module 170 during a reading operation. In the example illustrated in FIG. 4, it is assumed that the subsector data SB11 to SB18 explained with reference to FIG. 3 is stored in the buffer 150.

In the example illustrated in FIG. 4, the second verifying module 160 reads the subsector SB11 from the buffer 150 via the buffer manager 140 and stores it in the memory 171. Then, the second verifying module 160 verifies, with the use of the BCRC 11 appended to the subsector data SB11, whether the subsector data SB11 includes an error. If an error is detected, then the second verifying module 160 corrects the error with the use of the BECC 11 appended to the sector data SB11. In an identical manner, the second verifying module 160 reads the subsector SB12 from the buffer 150 via the buffer manager 140, stores it in the memory 171, and performs verification and correction of the subsector data SB12.

Every time the size of the verified sets of subsector data stored in the memory 171 reaches the transfer size of 1024 bytes, the interface control module 170 sends the data to the host apparatus 1. In the example illustrated in FIG. 4, after the data D11 and D12 get stored in the memory 171 and after the second verifying module 160 performs a verification operation and a correction operation with respect to the data D11 and D12, the interface control module 170 sends the data D11 and D12 to the host apparatus 1.

In an identical manner, after the data D13 and D14 get stored in the memory 171 and after the second verifying module 160 performs a verification operation and a correction operation with respect to the data D13 and D14, the interface control module 170 sends the data D13 and D14 to the host apparatus 1. Likewise, the interface control module 170 separately sends the data D15 and D16 as well as the data D17 and D18 to the host apparatus 1.

To each set of data sent to the host apparatus 1, the second verifying module 160 and the interface control module 170 respectively append a CRC and an ECC. For example, as illustrated on FIG. 4, the second verifying module 160 and the interface control module 170 respectively append a CRC and an ECC at the end of the data D11 as well as the data D12.

Explained below is the processing performed by each constituent element when the storage device 100 performs a writing operation. While performing a writing operation, the storage device 100 according to the second embodiment partitions the data received from the host apparatus 1 into sets of subsector data of the same size as in the case of a reading operation and stores the sets of subsector data obtained with partitioning in the buffer 150. Then, by coupling the sets of subsector data that has been stored in the buffer 150, the storage device 100 stores the data on a sector-by-sector basis in the driving module 110. In this way, by storing the sets of subsector data in the buffer 150 in an identical manner to that during a reading operation, the storage device 100 enables achieving cache hit while performing a reading operation.

Given below is the explanation of the processing performed by each constituent element illustrated in FIG. 2 during a writing operation. However, since the driving module 110 and the buffer 150 function in an identical manner to that during a reading operation, the explanation thereof is not repeated.

In the case when the storage device 100 performs a writing operation, the interface control module 170 receives data from the host apparatus 1 and stores that data in the memory 171. The data received from the host apparatus 1 has a CRC and an ECC appended thereto.

The second verifying module 160 performs a verification operation and a correction operation with respect to the data stored in the memory 171. Then, the second verifying module 160 partitions the verified data into sets of subsector data and appends a BCRC and a BECC to each set of the subsector data.

In the case when the storage device 100 performs a writing operation, the buffer manager 140 stores, in the buffer 150, the sets of subsector data that have been appended with respective BCRC and BECC by the second verifying module 160.

The processing performed by the second verifying module 160 and the buffer manager 140 during a writing operation is explained below with reference to FIG. 5. FIG. 5 is a schematic diagram of an example of the processing performed by the second verifying module 160 and the buffer manager 140 during a writing operation.

In the example illustrated in FIG. 5, the interface control module 170 receives data D20 that is equivalent to 1024 bytes and stores it in the memory 171. As illustrated in FIG. 5, the data D20 is appended with a CRC and an ECC. With the use of the CRC appended to the data D20, the second verifying module 160 verifies whether the data D20 includes an error. If an error is detected, then the second verifying module 160 corrects the error with the use of the ECC appended to the data D20.

Then, as illustrated in the lower part of FIG. 5, the second verifying module 160 partitions the verified data D20 into two sets of data D21 and D22, each equivalent to the size of 512 bytes. To the data D21 and D22, the second verifying module 160 appends respective BCRC and BECC. In the example illustrated in FIG. 5, the second verifying module 160 appends BCRC 21 and BECC 21 to the data D21 and appends BCRC 22 and BECC 22 to the data D22.

As illustrated in the lower part of FIG. 5, the buffer manager 140 then stores, in the buffer 150, subsector data SB21 and SB22 including respective BCRC and BECC appended by the second verifying module 160.

Every time data is received from the host apparatus 1, the second verifying module 160 performs a verification operation and a correction operation with respect to the data stored in the memory 171, partitions the verified data, and appends a BCRC and a BECC to each set of the partitioned data. Every time the second verifying module 160 generates the sets of subsector data, the buffer manager 140 stores them in the buffer 150.

Returning to the explanation with reference to FIG. 2, in the case when the storage device 100 performs a writing operation, the first verifying module 130 reads the sets of subsector data from the buffer 150 via the buffer manager 140 and verifies, with the use of the BCRC appended to each set of the subsector data, whether any set of the subsector data includes an error. If an error is detected, then the first verifying module 130 corrects the error with the use of the BECC appended to the corresponding subsector data.

Then, the first verifying module 130 removes the BCRC and the BECC from each set of the verified subsector data and couples the sets of subsector data to generate sector data equivalent to 4 KB. Subsequently, the first verifying module 130 appends a BCRC and a BECC to the generated sector data. In this way, by coupling the sets of subsector data, the first verifying module 130 generates the sector data.

In the case when the storage device 100 performs a writing operation, the drive control module 120 stores, in the driving module 110, the sector data generated by the first verifying module 130.

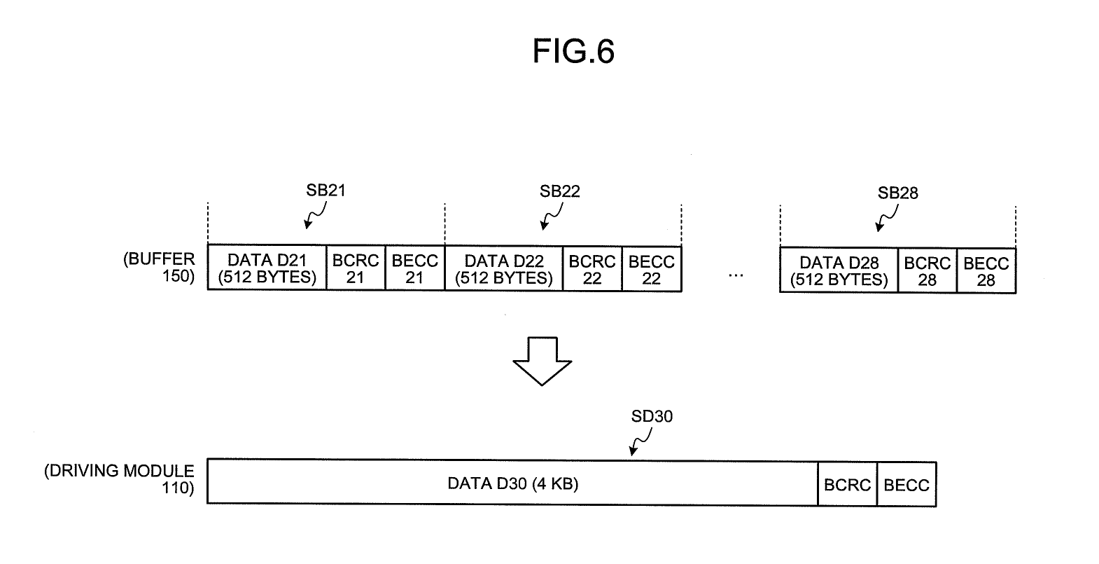

The processing performed by the first verifying module 130 and the drive control module 120 during a writing operation is explained below with reference to FIG. 6. FIG. 6 is a schematic diagram of an example of the processing performed by the first verifying module 130 and the drive control module 120 during a writing operation. In the example illustrated in FIG. 6, it is assumed that, in addition to the subsector data SB21 and SB22 explained with reference to FIG. 5, subsector data SB23 to SB28 is also stored in the buffer 150.

In the example illustrated in FIG. 6, the first verifying module 130 reads the subsector data SB21 from the buffer 150 via the buffer manager 140 and verifies, with the use of the BCRC 21 appended to the subsector data SB21, whether the subsector data SB21 includes an error. If an error is detected, then the first verifying module 130 corrects the error with the use of the BECC 21 appended to the sector data SB21. In an identical manner, the first verifying module 130 performs a verification operation and a correction operation with respect to each of the subsector data SB22 to SB28.

Then, from the verified subsector data SB21 to SB28, the first verifying module 130 respectively removes the BCRC 21 to the BCRC 28 and removes the BECC 21 to the BECC 28 and couples the subsector data SB21 to SB28 to generate data D30 equivalent to 4 KB. Subsequently, the first verifying module 130 appends a BCRC and a BECC to the generated data D30. In this way, by coupling the sets of subsector data, the first verifying module 130 generates sector data SD30. The drive control module 120 stores, in the driving module 110, the sector data SD30 generated by the first verifying module 130.

In this way, while performing a writing operation, the storage device 100 according to the second embodiment stores the data on a subsector-by-subsector basis in the buffer 150 and stores the data on a sector-by-sector basis in the driving module 110.

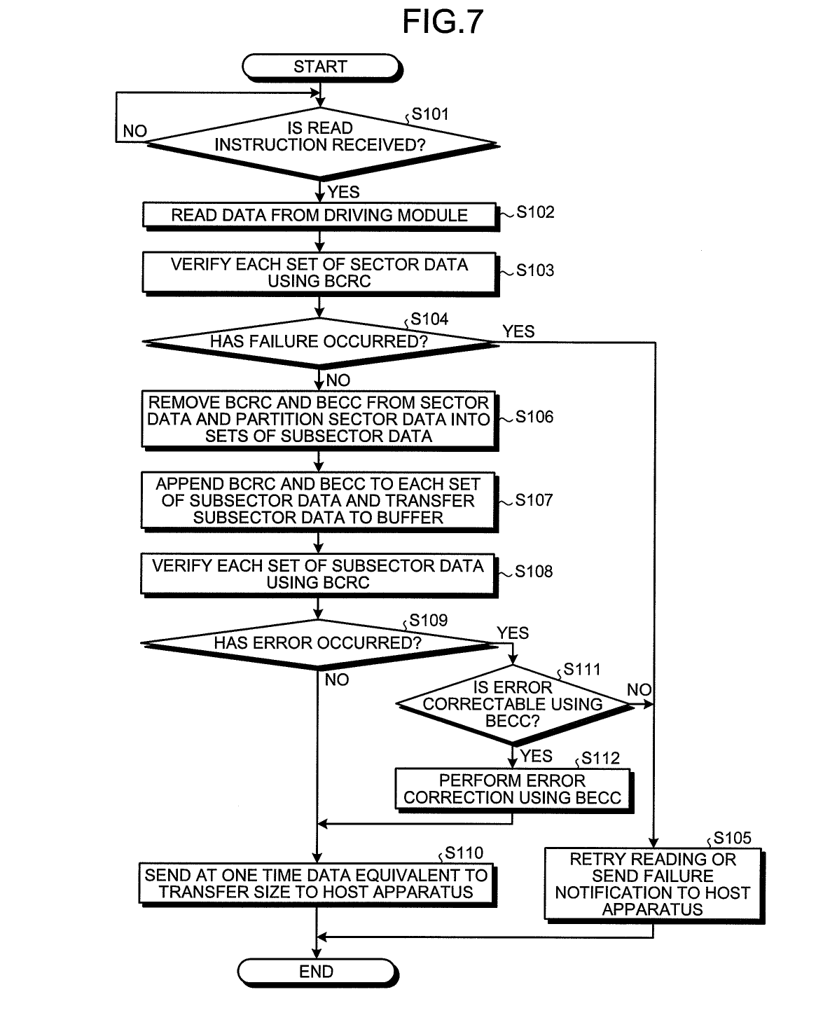

Explained below with reference to FIG. 7 is the processing sequence in a reading operation performed by the storage device 100 according to the second embodiment. FIG. 7 is a flowchart for explaining the processing sequence in a reading operation performed by the storage device 100 according to the second embodiment.

As illustrated in FIG. 7, upon receiving a read instruction (Yes at S101), the drive control module 120 in the storage device 100 reads data on a sector-by-sector basis from the driving module 110 (S102).

Subsequently, with the use of a BCRC appended to each set of the sector data read by the drive control module 120, the first verifying module 130 verifies whether any set of the sector data includes an error (S103). If an error is detected, then the first verifying module 130 corrects the error with the use of a BECC appended to the corresponding sector data.

If a failure occurs while performing error correction of the sector data (Yes at S104), then the first verifying module 130 either retries to read the sector data from the driving module 110 or sends a failure notification to the host apparatus 1 (S105).

On the other hand, if no error is detected in the sector data or if no failure occurs while performing error correction of the sector data (No at S104), then the first verifying module 130 removes the BCRC and the BECC from each set of the verified sector data and partitions each set of the sector data into sets of subsector data of a smaller size than the sector size (S106).

The first verifying module 130 then appends a BCRC and a BECC to each set of the subsector data obtained with partitioning and transfers the sets of subsector data to the buffer 150 (S107). More particularly, the buffer manager 140 stores, in the buffer 150, the sets of subsector data appended with respective BCRC and BECC by the first verifying module 130.

Subsequently, the second verifying module 160 reads the sets of subsector data from the buffer 150 via the buffer manager 140 and verifies whether any set of the subsector data includes an error (S108). More particularly, the second verifying module 160 stores, in the memory 171, the sets of subsector data read from the buffer 150 and verifies, with the use of the BCRC appended to each set of the subsector data, whether any set of the subsector data includes an error.

If no error is detected by the second verifying module (No at S109), then the interface control module 170 sends at one time the subsector data equivalent to the transfer size from the memory 171 to the host apparatus 1 (S110).

On the other hand, if an error is detected (Yes at S109), then the second verifying module 160 determines whether the error can be corrected with the use of the BECC appended to the corresponding set of subsector data. If the error is correctable using the BECC (Yes at S111), then the second verifying module 160 corrects the error of the corresponding subsector data (S112). On the other hand, if the error is not correctable using the BECC (No at S111), then the second verifying module 160 either retries to read the subsector data from the buffer 150 or sends a failure notification to the host apparatus 1 (S105).

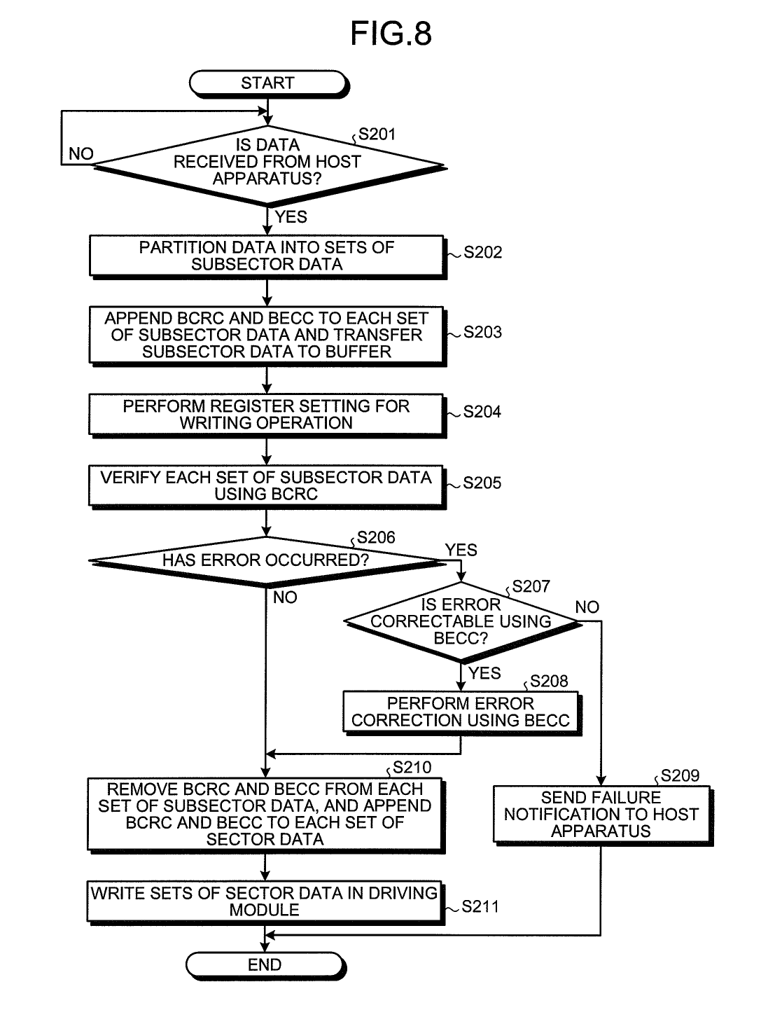

Explained below with reference to FIG. 8 is the processing sequence in a writing operation performed by the storage device 100 according to the second embodiment. FIG. 8 is a flowchart for explaining the processing sequence in a writing operation performed by the storage device 100 according to the second embodiment.

As illustrated in FIG. 8, upon receiving target data for writing (Yes at 5201), the interface control module 170 in the storage device 100 stores the received data in the memory 171 (S202).

Subsequently, the second verifying module 160 performs a verification operation and a correction operation with respect to the data stored in the memory 171 and partitions the verified data into sets of subsector data (S202). Then, the second verifying module 160 appends a BCRC and a BECC to each set of the subsector data obtained with partitioning and transfers the sets of subsector data to the buffer 150 (S203).

Then, the storage device 100 performs register setting for writing operation (S204). Herein, the register setting for writing operation indicates processing for determining whether to perform seek control of the magnetic head or perform logical block addressing (LBA) of the writing destination.

The first verifying module 130 then reads the sets of subsector data from the buffer 150 via the buffer manager 140 and verifies whether any set of the subsector data includes an error (S205). More particularly, with the use of the BCRC appended to each set of the subsector data that is read from the buffer 150, the first verifying module 130 verifies whether any set of the subsector data includes an error.

If an error is detected (S206), then the first verifying module 130 determines whether the error can be corrected with the use of the BECC appended to the corresponding set of subsector data. If the error is correctable using the BECC (Yes at S207), then the first verifying module 130 corrects the error of the corresponding subsector data (S208). On the other hand, if the error is not correctable using the BECC (No at S207), then the first verifying module 130 sends a failure notification to the host apparatus 1 (S209).

Subsequently, the first verifying module 130 removes the BCRC and the BECC from each set of the verified subsector data, couples the sets of subsector data to generate sets of sector data, and appends a BCRC and a BECC to each of the generated sets of sector data (S210). The drive control module 120 then writes, in the driving module 110, the sets of sector data generated by the first verifying module 130 (S211).

Meanwhile, if no error is detected in the subsector data (No at 5206), then the first verifying module 130 removes the BCRC and the BECC from each of the verified subsector data, couples the subsector data to generate sets of sector data, and appends a BCRC and a BECC to each of the generated sets of sector data (S210). The drive control module 120 then writes, in the driving module 110, the sets of sector data generated by the first verifying module 130 (S211).

As described above, while performing a reading operation, the storage device 100 according to the second embodiment partitions each set of the sector data, which is read on a sector-by-sector basis from the driving module 110, into sets of subsector data, appends a BCRC and a BECC to each set of the subsector data obtained with partitioning, and then stores the sets of subsector data in the buffer 150. Subsequently, the storage device 100 reads the sets of subsector data from the buffer 150, stores them in the memory 171, and performs a verification operation with respect to the stored sets of subsector data. Subsequently, the storage device 100 sends at one time the subsector data equivalent to the transfer size from the memory 171 to the host apparatus 1. In this way, even if the sector size of the driving module 110 is large, the storage device 100 according to the second embodiment stores the sets of subsector data obtained with partitioning in the memory 17. Hence, the memory 171 is saved from being used in a large capacity. That enables achieving expansion of the sector size without having to increase the capacity of the memory 171.

In the case of performing a writing operation, the storage device 100 partitions the received data into sets of subsector data, appends a BCRC and a BECC to each set of the subsector data, and stores the sets of subsector data in the buffer 150. Then, the storage device 100 verifies each set of the subsector data read from the buffer 150 and stores the verified subsector data in the driving module 110. Thus, during a writing operation, by storing the sets of subsector data in the buffer 150 in an identical manner to that during a reading operation, the storage device 100 enables achieving cache hit while performing a reading operation.

Moreover, while performing a writing operation, the storage device 100 removes the BCRC and the BECC from each set of the subsector data read from the buffer 150, couples the sets of subsector data to generate sector data, and stores only the sector data in the driving module 110. For that reason, the storage device 100 according to the second embodiment is able to prevent the capacity of the driving module 110 from getting burdened.

More particularly, assume that the storage device 100 stores the data on a subsector-by-subsector basis in the driving module 110. However, in that case, each set of the subsector data is separately appended with a BCRC and a BECC, which bears heavily on the capacity of the driving module 110. In regard to that issue, by storing the data on a sector-by-sector basis in the driving module, the storage device 100 according to the second embodiment is able to prevent the capacity of the driving module 110 from getting burdened.

Meanwhile, the explanation in the second embodiment is given under the assumption that the sector size is 4 KB, the subsector size is 512 bytes, and the transfer size of data to be communicated with a host apparatus is 1024 bytes. However, none of the sector size, the subsector size, and the transfer size is limited to the abovementioned values. For example, the sector size can also be 1 KB or 8 KB, the subsector size can also be 1 KB, and the transfer size can also be 512 bytes.

The memory device disclosed in the present invention can also be implemented in other forms that are different than the description given in the abovementioned embodiments. Thus, in a third embodiment is given the description of other embodiments for implementing the memory device disclosed in the present invention.

Of the processes described in the first two embodiments, all or part of the processes explained as being performed automatically can be performed manually. Similarly, all or part of the processes explained as being performed manually can be performed automatically by a known method. Besides, the processing procedures, the control procedures, specific names, various data, and information including parameters described in the embodiments or illustrated in the drawings can be changed as required unless otherwise specified.

Moreover, the constituent elements of each device illustrated in the drawings are merely conceptual, and need not be physically configured as illustrated. The constituent elements, as a whole or in part, can be separated or integrated either functionally or physically based on various types of loads or use conditions. The process functions performed by the device are entirely or partially realized by the CPU or computer programs that are analyzed and executed by the CPU, or realized as hardware by wired logic.

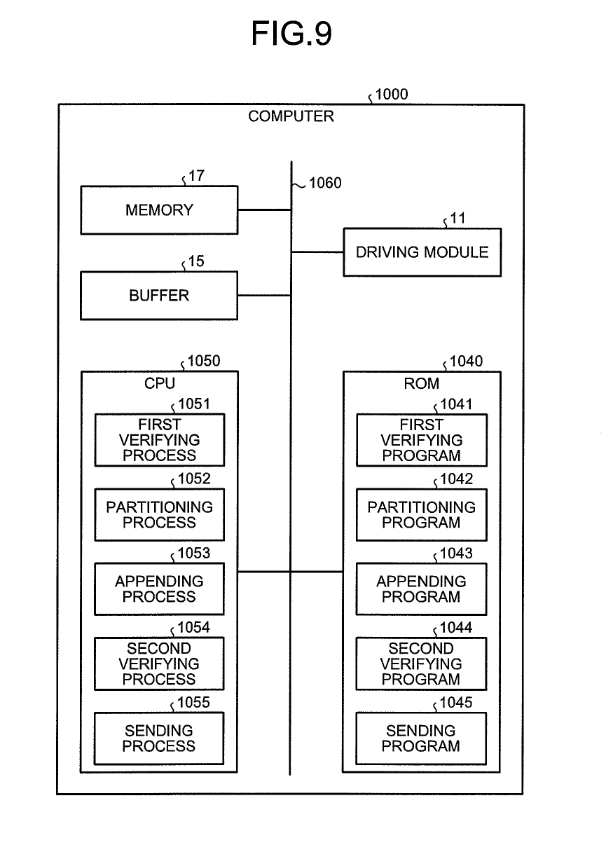

The processes described in the first two embodiments can be implemented by executing a program written in advance in a computer such as a personal computer (PC) or a workstation. Described below with reference to FIG. 9 is a computer that executes a data transfer program having identical functions to those of the memory device 10 according to the first embodiment.

FIG. 9 is an exemplary schematic diagram of a computer that executes the data transfer program. As illustrated in FIG. 9, a computer 1000 comprises the driving module 11, the buffer 15, the memory 17, a read only memory (ROM) 1040, and a central processing unit (CPU) 1050 that are interconnected by a bus 1060.

The data transfer program, which has identical functions to those of the memory device 10 according to the first embodiment, is stored in advance in the ROM 1040. More particularly, the ROM 1040 is used to store a first verifying program 1041, a partitioning program 1042, an appending program 1043, a second verifying program 1044, and a sending program 1045.

The CPU 1050 reads and executes the first verifying program 1041, the partitioning program 1042, the appending program 1043, the second verifying program 1044, and the sending program 1045. Consequently, as illustrated in FIG. 9, the first verifying program 1041, the partitioning program 1042, the appending program 1043, the second verifying program 1044, and the sending program 1045 respectively function as a first verifying process 1051, a partitioning process 1052, an appending process 1053, a second verifying process 1054, and a sending process 1055.

The first verifying process 1051 corresponds to the first verifying module 12 illustrated in FIG. 1, the partitioning process 1052 corresponds to the partitioning module 13 illustrated in FIG. 1, the appending process 1053 corresponds to the appending module 14 illustrated in FIG. 1, the second verifying process 1054 corresponds to the second verifying module 16 illustrated in FIG. 1, and the sending process 1055 corresponds to the sending module 18 illustrated in FIG. 1.

Meanwhile, the programs 1041 to 1045 need not be stored in the ROM 1040 from the start. Alternatively, for example, it is possible to store those programs in a portable physical medium such as a flexible disk (FD), a compact disk read only memory (CD-ROM), a digital versatile disk (DVD), a magnetic optical disk, or a chip card; in a fixed physical medium such as an HDD installed inside or outside of the computer 1000; or in another computer (or server) that is connected to the computer 1000 via a public line, Internet, a local area network (LAN), or a wide area network (WAN). Thus, the computer 1000 can read the programs from, for example, a flexible disk and then execute the same.

The various modules of the systems described herein can be implemented as software applications, hardware and/or software modules, or components on one or more computers, such as servers. While the various modules are illustrated separately, they may share some or all of the same underlying logic or code.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A memory device configured to communicate data of a predetermined transfer size with respect to a host, the memory device comprising:
a driving module configured to store data on a sector-by-sector basis;
a first verifying module configured to verify sector data read on the sector-by-sector basis from the driving module during a reading operation;
a partitioning module configured to partition the sector data verified by the first verifying module into sets of subsector data, a size of each set of subsector data being smaller than a size of the sector data;
an appending module configured to append an error detecting code to each set of partitioned subsector data;
a second verifying module configured to store, in a predetermined memory, the sets of subsector data from a buffer for storing the sets of subsector data appended with respective error detecting codes by the appending module, and configured to verify the sets of subsector data in the memory using respective error detecting codes appended by the appending module; and
a transmitter configured to read the sets of subsector data verified by the second verifying module from the memory, and configured to transmit the verified sets of subsector data to the host with the transfer size.

2. The memory device of claim 1, wherein
the appending module is configured to append an error correcting code to each set of subsector data, and
the second verifying module is configured to correct the sets of subsector data using respective error correcting codes appended by the appending module when an error is detected as a result of the verification using the error detecting code.

3. The memory device of claim 1, wherein,
the second verifying module is configured to partition data received from the host into sets of subsector data during a writing operation, and is configured to append an error detecting code to each of the sets of subsector data obtained with partitioning, and
the first verifying module is configured to verify the sets of subsector data retrieved from a buffer that is used in storing the sets of subsector data appended with respective error detecting codes by the second verifying module, using respective error detecting codes appended by the second verifying module, and is configured to store verified sets of subsector data in the driving module.

4. The memory device of claim 3, wherein
the second verifying module is configured to append an error correcting code to each set of subsector data obtained with partitioning, and
when an error is detected as a result of the verification using the error detecting code, the first verifying module is configured to correct the sets of subsector data using respective error correcting codes appended by the second verifying module.

5. The memory device of claim 4, wherein during the data writing operation, the first verifying module is configured to remove the error detecting codes and the error correcting codes appended by the second verifying module from the verified sets of subsector data, and is configured to couple the verified sets of subsector data to obtain data on the sector-by-sector basis and store the data on the sector-by-sector basis in the driving module.

6. A data transfer control device for controlling a memory device configured to communicate data of a predetermined transfer size with respect to a host, the data transfer control device comprising:
a first verifying module configured to verify, during a reading operation, sector data read on a sector-by-sector basis from a driving module that is used in storing data on the sector-by-sector basis;
a partitioning module configured to partition the sector data verified by the first verifying module into sets of subsector data, a size of each set of subsector data being smaller than a size of the sector data;
an appending module configured to append an error detecting code to each set of partitioned subsector data;
a second verifying module configured to store, in a predetermined memory, the sets of subsector data from a buffer for storing, the sets of subsector data appended with respective error detecting codes by the appending module, and configured to verify the sets of subsector data in the memory using respective error detecting codes appended by the appending module; and
a transmitter configured to read the sets of subsector data verified by the second verifying module from the memory, and configured to transmit the verified sets of subsector data to the host by the transfer size.

7. A data transfer method performed by a memory device configured to communicate data of a predetermined transfer size with respect to a host with, the data transfer method comprising:
verifying, during a reading operation, sector data read on a sector-by-sector basis from a driving module that is used in storing data on the sector-by-sector basis;
partitioning the verified sector data verified into sets of subsector data, a size of each set of subsector data being smaller than a size of the sector data;
appending an error detecting code to each set of partitioned subsector data;
storing, in a predetermined memory, the sets of subsector data from a buffer for storing the sets of subsector data appended with respective error detecting codes;
verifying the sets of subsector data stored in the memory using respective appended error detecting codes; and
reading, from the memory, the verified sets of subsector data, and sending the verified sets of subsector data to the host with the transfer size.
